(19) United States
(12) Patent Application Publication
(10) Pub. No.: US 2022/0109440 A1
(43) Pub. Date: Apr. 7, 2022

(54) Circuit for Capturing Electrical Energy from Vibrating Molecular Charges

(71) Applicant: Bjorn J. Gruenwald, Newtown, PA (US)

(72) Inventor: Bjorn J. Gruenwald, Newtown, PA (US)

(21) Appl. No.: 17/460,171

(22) Filed: Aug. 28, 2021

Related U.S. Application Data
(63) Continuation of application No. 15/155,026, filed on May 15, 2016, now abandoned.
(60) Provisional application No. 62/162,250, filed on May 15, 2015.

(51) Int. Cl. H03K 17/687

(52) U.S. Cl. CPC H03K 17/687

(57) ABSTRACT

According to various implementations of the invention, a rectifier circuit may be configured to capture currents and/or voltages induced by a vibrating molecular charge. Any number of such rectifier circuits may be fabricated in series and/or in parallel to provide an electrical power source. In effect, various implementations of the invention capture or “harvest” thermal energy of the vibrating molecular charges and convert this energy into electrical energy. In some implementations of the invention, the rectifiers may comprise diodes. In some implementations of the invention, the rectifiers may comprise field effect transistors.

### FIELD OF THE INVENTION

The invention is generally related to capturing energy produced by vibrating charges, and more particularly, a circuit for converting thermal energy of vibrating molecular charges into electrical energy.

### BACKGROUND OF THE INVENTION

When a magnet moves back and forth relative to a wire, an oscillating voltage is induced across the wire. When such a wire is part of a closed circuit, an oscillating current will flow through the wire and the circuit. Such a phenomenon is well understood.

A moving or vibrating molecular charge, such as that produced by certain molecules, atoms, or atomic particles (e.g., electrons), may also induce such oscillating voltages and/or currents.

What is needed is a circuit for capturing energy from vibrating molecular charges.

### SUMMARY OF THE INVENTION

According to various implementations of the invention, a circuit including a rectifier (i.e., a rectifier circuit) may be configured to capture currents induced by a vibrating molecular charge. Any number of such rectifier circuits may be fabricated in series and/or in parallel to provide an electrical power source. In some implementations of the invention, such rectifier circuits may have feature sizes of less than 10 nanometers. Rectifier circuits in accordance with various implementations of the invention may capture thermal energy of the vibrating molecular charges and convert this energy into electrical energy.

According to various implementations of the invention, the rectifier circuit may comprise a field effect transistor (“FET”), including a metal oxide semiconductor field effect transistor (“MOSFET”), configured to capture currents induced by a vibrating molecular charge. Any number of such FETs may be fabricated in series and/or in parallel to provide an electrical power source. In some implementations of the invention, such FETs may have feature sizes of less than 10 nanometers. Rectifier circuits comprised of a FET may capture thermal energy of the vibrating molecular charges and convert this energy into electrical energy.

According to various implementations of the invention, the rectifier circuit may comprise a diode configured to capture currents induced by a vibrating molecular charge. Any number of such diodes may be fabricated in series and/or in parallel to provide an electrical power source. In some implementations of the invention, such diodes may have feature sizes of less than 10 nanometers. Rectifier circuits comprised of a diode may capture thermal energy of the vibrating molecular charges and convert this energy into electrical energy.

These implementations, their features and other aspects of the invention are described in further detail below.

### BRIEF DESCRIPTION OF THE DRAWINGS

FIG. 1 illustrates a rectifier circuit comprising a FET according to various implementations of the invention.

FIG. 2 illustrates a rectifier circuit comprising a FET according to various implementations of the invention.

FIG. 3 illustrates a rectifier circuit comprising a diode according to various implementations of the invention.

FIG. 4 illustrates a rectifier circuit according to various implementations of the invention.

FIG. 5 illustrates a fabricated rectifier circuit according to various implementations of the invention.

### DETAILED DESCRIPTION

Various implementations of the invention are directed towards capturing or “harvesting” energy from vibrating molecular charges and converting that energy into electrical energy. Small vibrating molecular charges (e.g., vibrating molecules, atoms, atomic particles, etc.) may induce small electrical currents in a closed circuit. However, such induced currents typically cancel one another out based on such vibrations occurring in random directions.

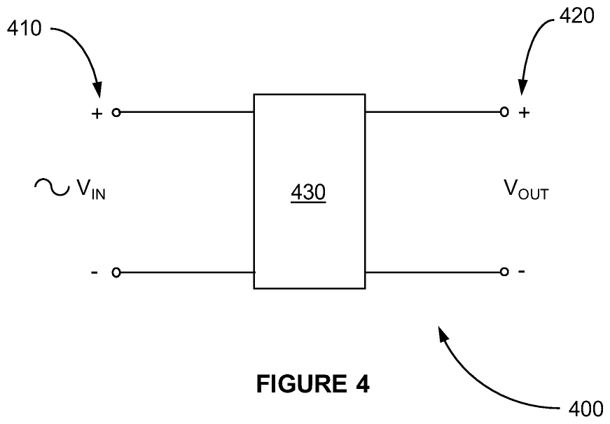

One mechanism to capture electrical energy provided by such induced currents is to employ a rectifier circuit 400 such as that illustrated in FIG. 4. Vibrating charges across input 410 may induce small electrical currents that may be captured by a rectifier 430 to produce electrical energy in the form of a voltage across output 420.

According to various implementations of the invention, a field effect transistor (“FET”) or metal oxide semiconductor field effect transistor (“MOSFET”) may be configured as a rectifier. A forward voltage drop of a FET or a MOSFET is virtually negligible (approximately 40 mV) because a gate of these FET devices control their impedance from nearly zero ohms to 10¹² ohms. As a result, FET devices may be configured as a rectifier without suffering from the larger forward voltage drop of other types of rectifiers.

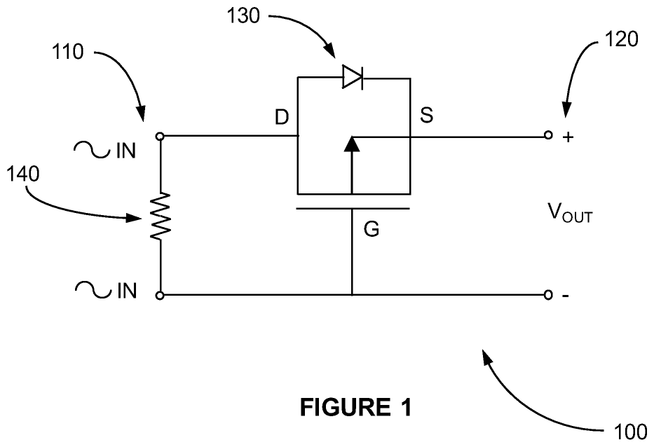

FIG. 1 illustrates a rectifier circuit 100 having an input 110 and a voltage output 120 according to various implementations of the invention. Rectifier circuit 100 includes a single MOSFET 130 (illustrated in FIG. 1 as a P channel type MOSFET). As illustrated, a drain (“D”) of MOSFET 130 is coupled to a first terminal of input 110, a source CS″) of MOSFET 130 is coupled to a first terminal (positive) of output 120, and a gate (“C”) of MOSFET 130 is coupled to a second terminal of input 110 and a second terminal (negative) of output 120.

According to various implementations of the invention, a vibrating molecular charge in a vicinity of a wire 140 (illustrated as a conductor with an inherent resistance) induces a fluctuating current in wire 140; and that current is rectified by MOSFET 130 to produce a DC voltage across output 120. In application, multiple vibrating molecular charges in vicinity of wire 140 induce fluctuating currents in wire 140; and those currents are collectively rectified by MOSFET 130 to produce an aggregate DC voltage across output 120 (i.e., “Vₒᵤₜ”).

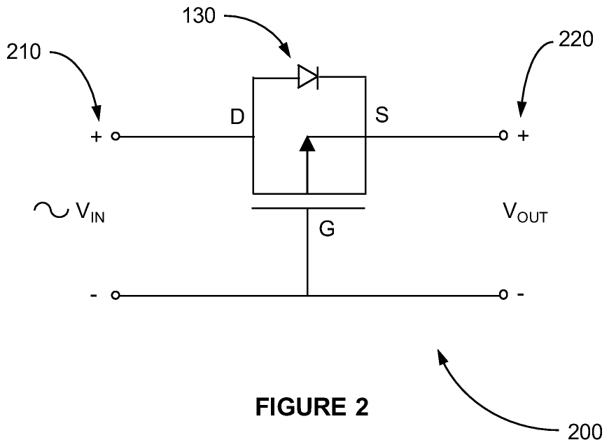

FIG. 2 illustrates a rectifier circuit 200 having a voltage input 210 and voltage output 220 according to various implementations of the invention. According to various implementations of the invention, a vibrating molecular charge in a vicinity of voltage input 210 (i.e., without wire 140) induces a fluctuating voltage across voltage input 210. In application, multiple vibrating molecular charges in vicinity of voltage input 210 induce fluctuating voltages across voltage input 210; and those voltages are collectively rectified by MOSFET 130 to produce an aggregate DC voltage across output 220 (i.e., “Vₒᵤₜ”).

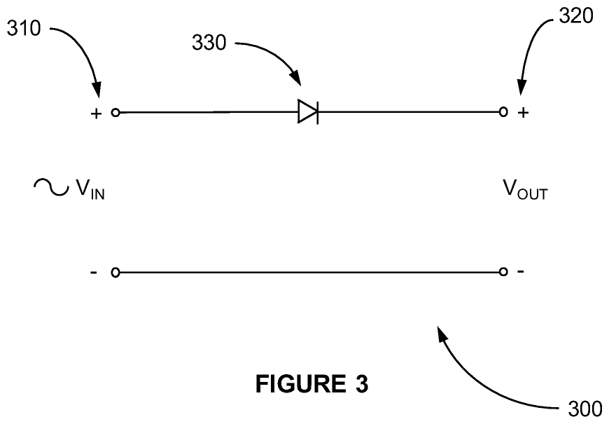

FIG. 3 illustrates a rectifier circuit 300 having an input 310 and a voltage output 320 according to various implementations of the invention. Rectifier circuit 300 includes a single diode 330. As illustrated, an anode of diode 330 is coupled to a first terminal of input 310 and a cathode of diode 330 is coupled to a corresponding first terminal of output 320. Various types of diodes may be used as would be appreciated.

According to various implementations of the invention, a vibrating molecular charge in a vicinity of input 310 induces a fluctuating voltage across input 310. In application, multiple vibrating molecular charges in vicinity of voltage input 310 induce fluctuating voltages across voltage input 310; and those voltages are collectively rectified by diode 330 to produce an aggregate DC voltage across output 320 (i.e., “Vₒᵤₜ”). As would be appreciated, diodes experience a barrier voltage, or forward voltage, across them. For example, silicon diodes experience a forward voltage drop of 0.75V, whereas germanium diodes experience a forward voltage drop of 0.25V. The fluctuating voltages across voltage input 310 would have to be sufficient to overcome such barrier voltages as would be appreciated.

The rectifier circuits illustrated in FIGS. 1-3 are configured as half-wave rectifier circuits as would be appreciated. Other forms of rectifier circuits (e.g., full-wave, etc.) may be used in various implementations of the invention as would also be appreciated.

Semiconductor manufacturing techniques are approaching feature sizes of less than 10 nanometers (nm); by the end of the decade, feature sizes are expected to be less than 5 nm. In some implementations of the invention, millions, billions, trillions, or more, of rectifiers 430, each having a feature size less than 200 nm, may be coupled together to provide an electrical power source. In some implementations of the invention, millions, billions, trillions, or more, of rectifiers 430, each having a feature size less than 100 nm, may be coupled together to provide an electrical power source. In some implementations of the invention, millions, billions, trillions, or more, of rectifiers 430, each having a feature size less than 50 nm, may be coupled together to provide an electrical power source. In some implementations of the invention, millions, billions, trillions, or more, of rectifiers 430, each having a feature size less than 20 nm, may be coupled together to provide an electrical power source. In some implementations of the invention, millions, billions, trillions, or more, of rectifiers 430, each having a feature size less than 10 nm, may be coupled together to provide an electrical power source. In some implementations of the invention, millions, billions, trillions, or more, of rectifiers 430, each having a feature size less than 5 nm, may be coupled together to provide an electrical power source.

As would be appreciated, smaller feature sizes provide for increased density of rectifiers 430 within a given footprint. In addition, rectifiers having smaller feature sizes may be more sensitive to smaller numbers vibrating charges.

In any of the foregoing implementations, some of rectifiers 430 may be coupled to one another in series, some may be coupled to one another in parallel, and/or some may be coupled in various combinations of in series and in parallel to provide both a sufficient output voltage and output current to act as an electrical power source for a variety of applications as would be appreciated.

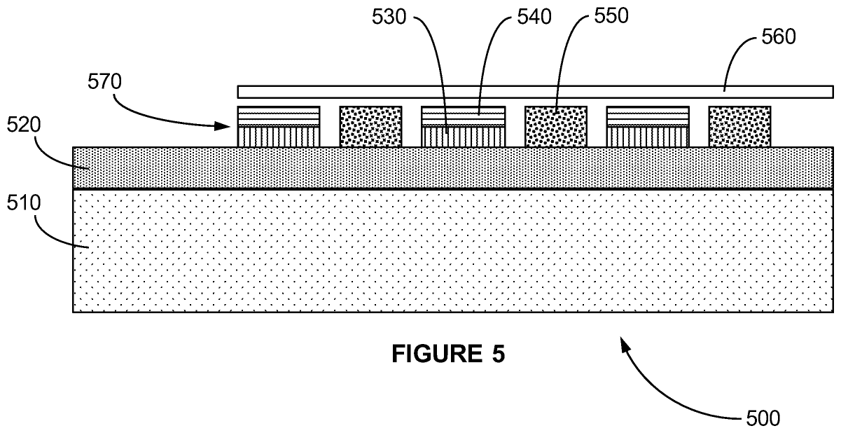

FIG. 5 illustrates an exemplary fabricated rectifier circuit 500 according to various implementations of the invention. In some implementations of the invention, rectifier circuit 500 includes a semiconductor layer 510, which may include silicon, germanium, or other type of semiconductor as would be appreciated. In some implementations the invention, rectifier circuit 500 includes a metal layer 520 deposited onto semiconductor layer 510. In some implementations the invention, rectifier circuit 500 includes N-type semiconductor 530 deposited onto metal layer 520. In some implementations the invention, rectifier circuit 500 includes P-type semiconductor 540 deposited onto N-type semiconductor 530. N-type semiconductor 530 and P-type semiconductor 540 together comprise a diode 570 as would be appreciated. Three such diodes 570 are illustrated in FIG. 5. As would be appreciated, in some implementations of the invention, N-type semiconductor 530 and P-type semiconductor 540 may be reversed (and rectifier circuit 500 reconfigured appropriately).

In some implementations the invention, rectifier circuit 500 includes a magnetic material 550 deposited onto metal layer 520 in between diodes 570. Magnetic material 550 may comprise ferrite, iron, cobalt, nickel, or other material with magnetic properties. Magnetic material 550 may be in powdered or solid form and may be sputtered or otherwise deposited onto metal layer 520. Magnetic material 550 serves as a source of vibrating charges (e.g., electrons) for rectifier circuit 500.

In some implementations of the invention, rectifier circuit 500 includes another metal layer 560 that serves as an interconnect coupling diodes 570. As thus illustrated in FIG. 5, metal layer 560 couples the cathodes of diodes 570 to one another and metal layer 520 couples the anodes of diodes 570 to one another. While three diodes 570 are illustrated in FIG. 5, any number of diodes 570 may be configured in rectifier circuit 500 depending on the size of the underlying wafer, feature sizes, etc., as would be appreciated.

In rectifier circuit 500, diodes 570 are coupled together in parallel to one another. In some implementations of the invention, any number of these rectifier circuits 500 may be subsequently coupled together in series to serve as a power supply as would be appreciated. In some implementations of the invention, diodes 570 may be coupled together in series to one another in another configuration of rectifier circuit (not otherwise illustrated) as would be appreciated. In such implementations, any number of rectifier circuits having series-coupled diodes 570 may be subsequently coupled together in parallel to serve as a power supply as would be appreciated.

As thus described, various implementations of the invention convert thermal energy associated with vibrating molecular charges (i.e., energy of motion) into electrical energy. Some implementations of the invention may be used to provide cooling as conversion of thermal energy to electrical energy results in reduced motion of the vibrating molecular charges, and hence, lower temperatures, as would be appreciated.

While various aspects of the invention have been described as employing FETs or MOSFETs, other types of transistors may be used as would be appreciated. Further, while MOSFET 130 in rectifier circuit 100 is illustrated as a P channel MOSFET, an N channel MOSFET may be used and rectifier circuit 100 may be modified accordingly. Further, other rectifier circuits and/or configurations of rectifier circuits and/or other rectifying components may be used, such as, but not limited to a bridge rectifier, as would be appreciated.

While the invention has been described herein in terms of various implementations, it is not so limited and is limited only by the scope of the following claims, as would be apparent to one skilled in the art. These and other implementations of the invention will become apparent upon consideration of the disclosure provided above and the accompanying figures. In addition, various components and features described with respect to one implementation of the invention may be used in other implementations as well.

What is claimed is:

1. An electrical circuit comprising:
a plurality of field effect transistors, each having a feature size less than 200 nanometers and configured to capture voltages or currents induced by a plurality of vibrating molecular charges and to rectify such voltages or currents to produce an output voltage.

2. The electrical circuit of claim 1, wherein each of the plurality of field effect transistors is a metal oxide semiconductor field effect transistor.

3. The electrical circuit of claim 1, wherein each of the plurality of field effect transistors is a P channel metal oxide semiconductor field effect transistor.

4. The electrical circuit of claim 1, wherein each of the plurality of field effect transistors is an N channel metal oxide semiconductor field effect transistor.

5. The electrical circuit of claim 1, wherein at least one of the plurality of field effect transistors is coupled in series to at least one other of the plurality of field effect transistors.

6. The electrical circuit of claim 1, wherein at least one of the plurality of field effect transistors is coupled in parallel with at least one other of the plurality of field effect transistors.

7. The electrical circuit of claim 1, wherein each of the plurality of field effect transistors has a feature size less than 100 nm.

8. The electrical circuit of claim 1, wherein each of the plurality of field effect transistors has a feature size less than 50 nm.

9. The electrical circuit of claim 1, wherein each of the plurality of field effect transistors has a feature size less than 20 nm.

10. The electrical circuit of claim 1, wherein each of the plurality of field effect transistors has a feature size less than 10 nm.

11. The electrical circuit of claim 1, wherein each of the plurality of field effect transistors has a feature size less than 5 nm.

12. An electrical circuit comprising:
a plurality of rectifiers, each having a feature size less than 10 nanometers and configured to capture voltages or currents induced by a plurality of vibrating molecular charges and to rectify such voltages or currents to produce an output voltage.

13. The electrical circuit of claim 12, wherein each of the plurality of rectifiers is a half-wave rectifier.

14. The electrical circuit of claim 12, wherein each of the plurality of rectifiers is a full-wave rectifier.

15. The electrical circuit of claim 12, wherein each of the plurality of rectifiers is a diode.

16. The electrical circuit of claim 13, wherein each of the plurality of rectifiers is a diode.

17. The electrical circuit of claim 13, wherein each of the plurality of rectifiers is a MOSFET.
